(19) United States
(12) Patent Application Publication
(10) Pub. No.: US 2018/0375239 A1
(43) Pub. Date: Dec. 27, 2018

(54) LIQUID METAL CIRCUIT ELEMENT CONNECTOR

(71) Applicant: Microsoft Technology Licensing, LLC, Redmond, WA (US)

(72) Inventor: James David HOLBERY, Bellevue, WA (US)

(73) Assignee: Microsoft Technology Licensing, LLC, Redmond, WA (US)

(21) Appl. No.: 15/631,506

(22) Filed: Jun. 23, 2017

(51) Int. Cl. H01R 13/03; H05K 7/10; H01R 13/22; H01R 12/52

(52) U.S. Cl. CPC H01R 13/03; H01R 12/52; H01R 13/22; H05K 7/1061

(57) ABSTRACT

Examples disclosed herein relate to an electrical connector interfacing a solid conductor and a liquid conductor. One example provides a connector for connecting to a liquid metal circuit element, the connector having a body defining a channel configured to contain a liquid metal, the body being configured to interface mechanically with the liquid metal circuit element, and a conductive path disposed within the channel and exposed to an interior of the channel to form a first electrical interface configured to interface with the liquid metal circuit element, the conductive path also comprising a second electrical interface.

### BACKGROUND

Various types of connectors may be used to connect electronic components in a device.

### SUMMARY

Examples are disclosed that relate to a connector for connecting a liquid metal circuit element to a solid conductor. One example provides a connector including a body defining a channel configured to contain a liquid metal, the body being configured to interface mechanically with the liquid metal circuit element. The connector also comprises a conductive path disposed within the channel and exposed to an interior of the channel to form a first electrical interface configured to interface with the liquid metal circuit element, the conductive path also comprising a second electrical interface.

Another example provides a connector system for connecting to a plurality of liquid metal circuit elements, the connector system comprising a plurality of integrated connectors, each connector comprising a body defining a channel configured to contain a liquid metal, the body being configured to interface mechanically with a liquid metal circuit element and incorporating a conductive path between a first electrical interface located at an interior surface of the channel and a second electrical interface.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1A shows a front view of an example computing system.

FIG. 1B shows a side view of the example computing system of FIG. 1A.

FIG. 1C shows a side view of the example computing system of FIG. 1A in a closed state.

FIG. 2. shows an example connector system comprising a plurality of connectors for connecting liquid and solid conductors.

FIG. 3 shows another example connector for connecting liquid and solid conductors.

FIG. 4 shows another example connector system for connecting a solid conductive element to a liquid metal circuit element.

FIG. 5 shows an example clothing item comprising conductive fibers and a connector system configured to connect the conductive fibers to a liquid metal circuit element.

### DETAILED DESCRIPTION

Liquid metal circuit elements may be incorporated into a variety of devices, for example, to provide electrical pathways between device components. As a more specific example, some electronic devices may include hinges, joints, fabric components, and other regions configured to flex between electronic components. In such regions, a liquid metal circuit element may be utilized to electrically connect the device components and maintain a conductive path as the device components are bent and/or rotated relative to one another. In contrast, a solid conductor, such as a copper trace or wire, may fatigue and/or break after a number of bend cycles.

A liquid metal circuit element may take the form of a liquid conductor such as eutectic gallium-indium (EGaIn) or other suitable gallium-containing material, formed on and/or encapsulated in a flexible material, such as polyimide and/or polydimethylsiloxane. In some examples, the liquid metal circuit element may take the form of a liquid metal disposed over a solid conductive trace as a self-healing component, or a liquid metal contained within a microfluidic conduit. In either case, the use of a liquid metal circuit element may help avoid circuit breakage from repeated flexing compared to connections that use only solid metal traces.

However, electrically connecting a solid conductor to a liquid metal circuit element may present challenges. For example, where a wire is inserted through an encapsulant layer (e.g. of a liquid metal-containing microfluidic conduit) to interface with a liquid metal, repeated flexing of the microfluidic conduit may cause the wire to detach, resulting in a loss of electrical conductivity.

Accordingly, examples are disclosed that relate to connecting a liquid metal circuit element to a solid conductor that may help to avoid such problems. In one example, a connector may be formed by insert molding a body defining a channel incorporating one or more conductive elements, such that the one or more conductive elements are contained at least partially within the body and exposed to an interior surface of the channel to form a first interface. The conductive element(s) may alternatively or additionally be incorporated by deposition on an interior surface of the channel after forming the body of the connector. The connector also includes a second interface configured to be connected to a solid conductor. When connected to a liquid metal circuit element and a solid conductor, liquid metal from the liquid metal circuit element enters the channel and contacts the conductive element, thereby forming a conductive path between the solid conductor and the liquid conductor. The molding of the conductive elements in the body may provide for a robust connection to a solid circuit element, and the channel may be configured to form a tight seal with the liquid metal circuit element, thereby helping to avoid problems such as detachment, leakage, and weakness described above.

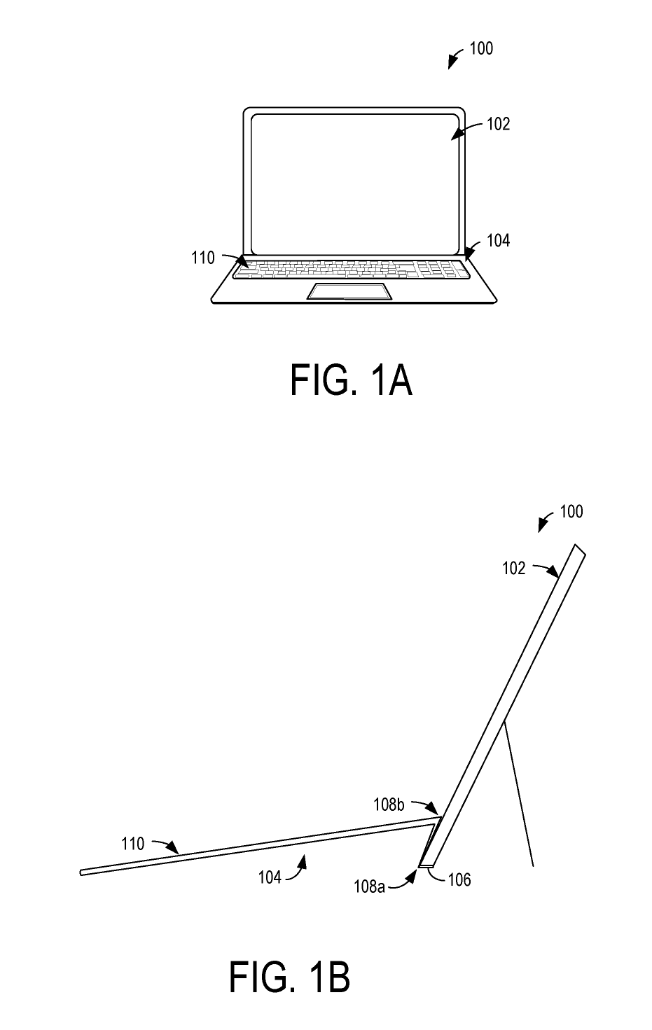

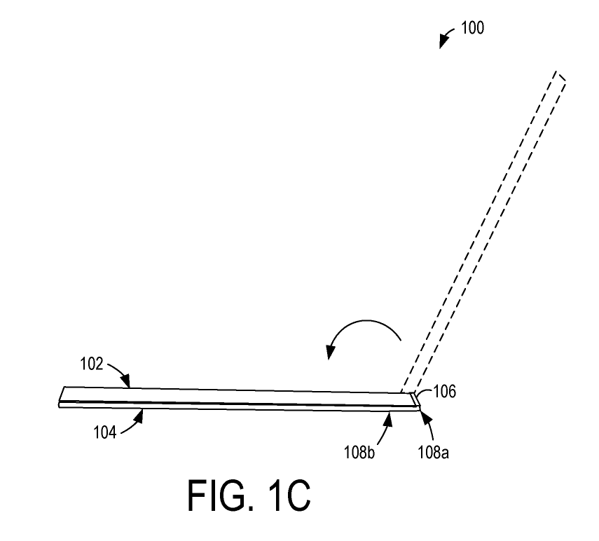

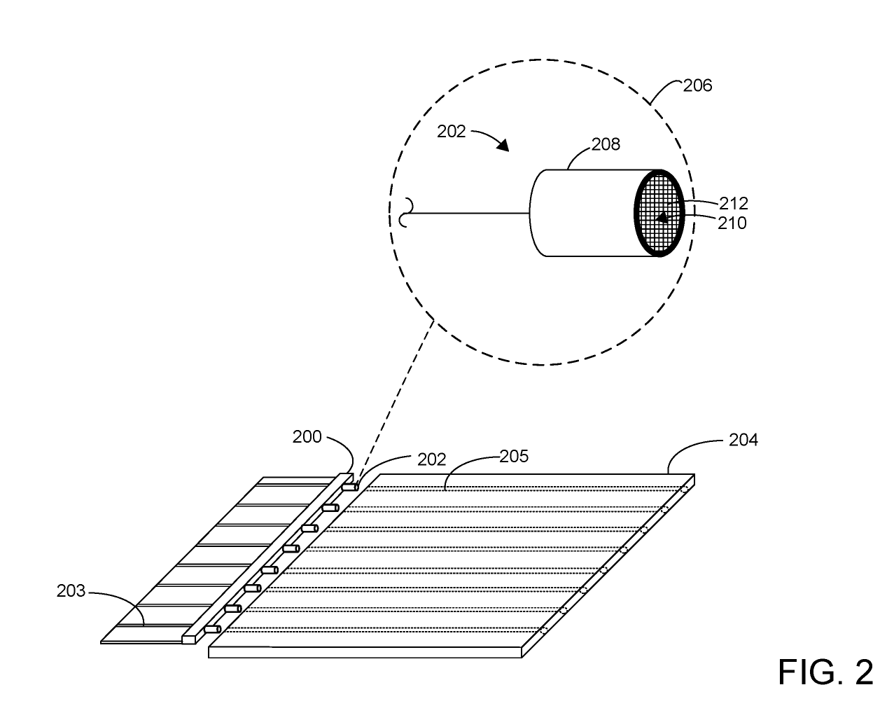

Prior to discussing these examples, FIGS. 1A-1C show an example computing system 100 in the form of a tablet having a display 102. The computing system is connected to a detachable keyboard unit 104 via a connector 106. The keyboard unit 104 comprises a connector 106 that electrically connects keys 110 and other electrical components of the keyboard unit 104 to the computing system 100.

The keyboard unit 104 and the connector positioned therein bend around a bottom corner of the display to a front of the display 102 in a first flex region 108a. As illustrated, the bend in this region is relatively sharp, conforming closely to the corner of the computing system 100. The keyboard unit 104 continues up the front surface of the display, and bends sharply down and away from the front surface of the display in a second flex region 108b. The bend in this region is also sharp. FIG. 1C shows flex region 108b in a straightened configuration when the computing device 100 and keyboard unit 104 are in a “closed” position, as opposed to an “open” position shown in FIGS. 1A-1B. Flex region 108a also may be straightened in a similar manner, for example, when the keyboard unit 104 is removed from the computing device. In other examples, an electronic device that utilizes a connector may take any other suitable form.

As the keyboard unit 104 potentially may be moved between the “open” and “closed” positions, as well as other possible positions, multiple times a day for years of use, the flex regions 108a-b may flex a very large number of times during the device lifetime. Thus, a liquid metal circuit element may be used to help prevent loss of conductivity in the flex regions 108a-b in an event that a solid conductor in a trace and/or wire may break.

FIG. 2 shows an example connector system 200 that may be utilized to connect to a liquid metal circuit element, such as one useable in the flex regions 108a-b of the example of FIG. 1, to solid conductors in an electronic device. The connector system 200 includes an integrated plurality of connectors 202 configured to interface a plurality of solid conductors (e.g. traces 203 on a substrate, wires).

FIG. 2 also shows an example liquid metal circuit element 204 comprising a plurality of conduits 205 each containing liquid metal. Each connector 202 of the connector system 200 is configured to mechanically and electrically interface with a corresponding fluidic conduit 205 containing a liquid metal conductor via a channel 210, shown in magnified view 206. As described above, each channel 210 may comprise a body 208 containing a plurality of conductive elements 212 that are each at least partially exposed to an interior surface of the channel 210 to form a first electrical interface. When a channel 210 is connected to a conduit 205 containing a liquid metal conductor, the liquid metal conductor may enter the channel 210 and electrically connect with the plurality of conductive elements 212.

The connector system 200 may be formed in any suitable manner, such as via insert molding. In such a process, the plurality of conductive elements 212 for the channel 210 of each connector 202 may be placed in a corresponding location in a mold, and the mold may be filled with a moldable material (e.g. a thermoplastic material). The moldable material may then be hardened to incorporate the plurality of conductive elements with the body 208 of each connector 202. In other examples, the connector system 200 may be formed via a casting process, via 3-d printing, or in any other suitable method. The connector system 200 may be formed from any suitable electrically insulating material. In the specific example of a connector system formed by insert molding, example materials include, but are not limited to, polycarbonate, nylon, PET, ABS, and other thermoplastic materials.

Likewise, in some examples, the plurality of conductive elements 212 may be deposited on an interior surface of the channel 210 after molding, rather than being incorporated while forming the body 208 defining the channel 210. For example, conductive elements 212 may be formed by printing, deposition (e.g. physical vapor deposition), or other suitable method.

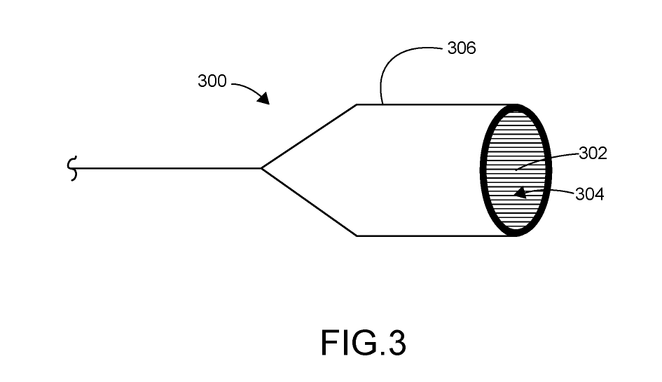

The conductive elements 212 may comprise any suitable structure. In some examples, the conductive elements comprise filaments arranged in a mesh structure, as shown in magnified view 206. A mesh structure may be securely coupled within the body 208 of a channel 210 by insert molding, and thus be resistant to being pulled or knocked out of the body 208. Further, a mesh structure that is at least partially exposed to an interior of the channel may present a relatively large surface area for electrically interfacing with the liquid metal conductor. As another example, FIG. 3 schematically shows an example connector 300 comprising a plurality of conductive elements in the form of conductive filaments 302 at least partially exposed to an interior of a channel 304. The filaments 302 also may present a relatively large surface area to a liquid metal conductor for forming an electrical connection, but are not arranged in an intersecting pattern, in contrast with the filaments of a mesh structure. In yet other examples, the conductive elements may have any other suitable form, including a single wire exposed to an interior of each channel.

Connector 300 may be configured as a stand-alone structure for connecting to a single liquid metal circuit element, or may be one of a plurality of connectors integrated in an electrically parallel arrangement. Likewise, in some examples, a single connector comprising a conductive mesh may be used as a stand-alone structure. Connector 300 comprises a body 306 defining a channel 304. The channel 304 may be a microfluidic channel having a diameter of tens to hundreds of micrometers and an interior surface configured to interface a liquid metal circuit element. Body 306 may be manufactured in any suitable manner. Examples include, but are not limited to, molding, casting, and additive manufacturing (3-d printing).

Each connector 202 may comprise any suitable configuration to connect to a liquid metal conduit. In some examples, the connector 202 may be configured as a male part to be fit within an interior of a corresponding liquid metal conduit. In such an example, an exterior surface of the channel may comprise a roughened texture or detent features configured to increase friction between the channel and conduit and thus reduce likelihood of the channel and conduit becoming disconnected. In other examples, a channel may be configured as a female end of an electrical connector, and thus conform around an exterior of a liquid metal conduit comprising a complementary male configuration. In connector systems comprising a female-configured connector, for each connector, an interior surface of a female-configured channel may be roughened or include detent features to achieve a similar fit.

In some examples, after insertion, the joint between the connector system 200 and liquid metal circuit element 204 may be sealed to help secure the connection. The connection may be sealed in any suitable manner. Examples include, but are not limited to, adhesives, polymer films (e.g. a layer of polydimethylsiloxane), and welding (e.g. where compatible thermoplastic materials are used to form the liquid metal circuit element and the connector system).

The conductive elements within each channel may be formed from any suitable material. In some examples, the conductive elements may be formed from a metal such as copper, gold, silver, aluminum, and alloys thereof. In other examples, the conductive elements may be formed from other conductive compounds, elements or composites. For example, the conductive elements may be formed from or coated with a conductive material configured to be wetted well by the liquid metal conductor. Such materials may include materials coated with conductors having a surface energy tuned to match or integrate with the liquid metal conductor. Examples include, but are not limited to, graphene coated fibers, silver coated fibers, silver coated textiles, silver nanowire coated surfaces, sputtered conductive surfaces, and other metallic fibers.

Likewise, any suitable liquid metal material may be used. Suitable liquid metal materials include liquid metals that are liquid at an intended operating temperature of a device. Examples include gallium, eutectic gallium/indium (eGaIn), eutectic gallium/indium/tin (Galinstan), and other gallium alloys.

As mentioned above, each connector 206 of connector system 200 may include a second interface to electrically interface with a solid conductor. In FIG. 2, each connector 206 includes a trace or wire (referred to herein generically as trace 203) that is electrically connected to the conductive elements within the channel and that also may be electrically connected to another solid conductor, such as another wire or a trace on a circuit board.

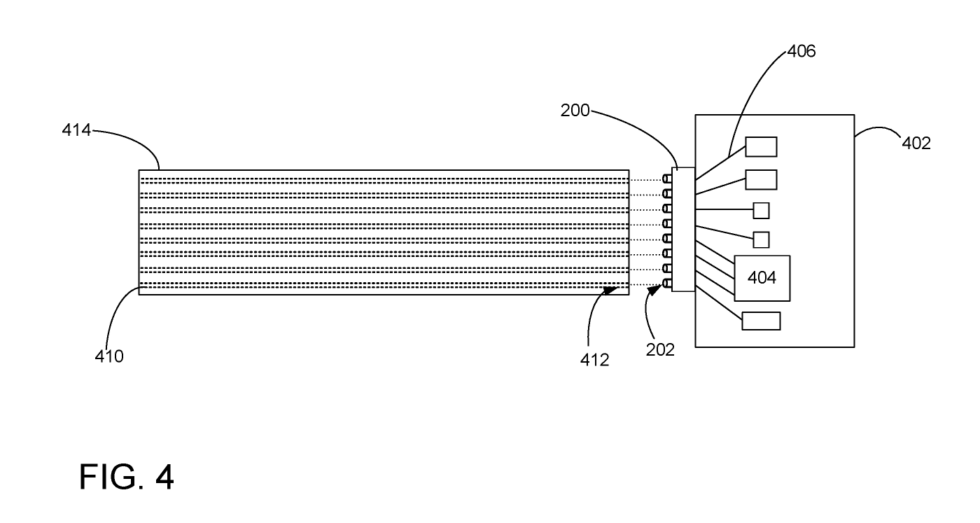

FIG. 4 shows a schematic top view of connector system 200 connected to a circuit board 402 comprising a plurality of electrical components (an example of which is indicated at 404). Each electrical component 404 is connected to the connector system 200 via a trace 406 printed on the circuit board. The connector system 200 may be coupled to the circuit board 402 in any suitable manner, such as by solder joints or an anisotropic conductive film.

As shown, each connector 202 is configured to “plug” into a complementary conduit 410 of a liquid metal circuit element 414 at a corresponding microfluidic inlet 412, thereby allowing a secure connection between liquid and solid circuit elements to be quickly formed. Liquid metal may be added to conduits 410 after connecting the connector system 200 to the liquid metal circuit element 414, for example, via vacuum filling, syringe injection, or in any other suitable manner. Liquid metal within each conduit 410 forms an electrical connection with conductive elements in the channel of each connector. A second electrical interface between each connector and each corresponding trace completes the electrical path between liquid metal circuit element 414 and circuit board 402.

It is to be understood that the connector and connector systems illustrated in FIGS. 2-4 are example configurations, and that other configurations are possible without departing from the scope of the disclosure. For example, while described above in the context of a molded part comprising channels having insert molded conductive elements, in other examples the body itself may be formed from a conductive material, such as a graphite- or graphene-containing composite material.

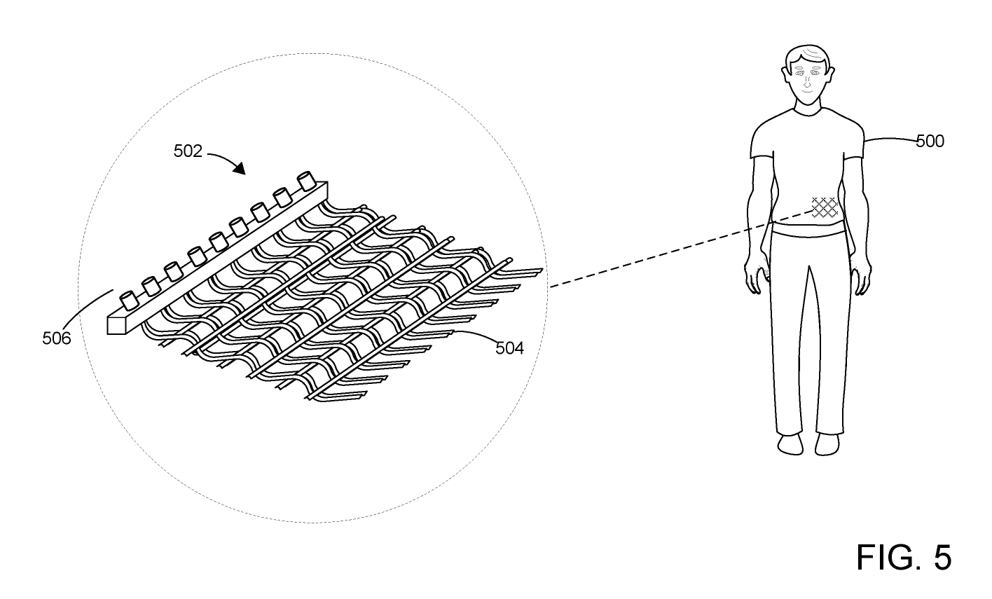

The example connectors disclosed herein may be used in any suitable electronic device. FIG. 5 shows an example electronic device in the form of a clothing item 500 comprising electronic elements. The clothing item 500 includes a connector system 502 to connect to a plurality of liquid metal-containing conduits on one side and to conductive fibers (yarn, thread, etc.) incorporated into the clothing on another side. Conductive clothing fibers 504 may be electrically connected to one or more circuit elements (e.g. liquid metal-containing sensors) incorporated into the clothing item 500 via connector system 502.

Another example provides a connector for a liquid metal circuit element, the connector comprising a body defining a channel configured to contain a liquid metal, the body being configured to interface mechanically with the liquid metal circuit element, and a conductive path comprising a plurality of conductive elements disposed within the channel and exposed to an interior of the channel to form a first electrical interface configured to interface with the liquid metal circuit element, and the conductive path also comprising a second electrical interface. In such an example, the plurality of conductive elements may be additionally or alternatively formed at least partially from a metal. In such an example or any preceding example, the plurality of conductive elements may additionally or alternatively comprise a mesh structure. In such an example or any preceding example, the body may additionally or alternatively be formed from a polymer material. In such an example or any preceding example, the body may additionally or alternatively be formed at least partially from a conductive polymer. In such an example or any preceding example, the conductive path may additionally or alternatively be at least partially incorporated into the body. In such an example or any preceding example, the body defining the channel may additionally or alternatively be configured as a male end of a mechanical connector. Such an example or any preceding example may additionally or alternatively further comprise a liquid metal positioned within the channel. In such an example or any preceding example, the second electrical interface may additionally or alternatively be configured to connect to one or more of a wire and a trace. In such an example or any preceding example, the connector may additionally or alternatively be integrated with a plurality of other connectors.

Another example provides a connector system comprising an integrated plurality of connectors, each connector comprising a body defining a channel configured to contain a liquid metal, the body being configured to interface mechanically with a liquid metal circuit element and incorporating a conductive path between a first electrical interface located at an interior surface of the channel and a second electrical interface. In such an example or any preceding example, the conductive path may additionally or alternatively further comprise one or more conductive elements contained at least partially within the body and exposed to an interior of the channel, the one or more conductive elements each being configured to interface with the liquid metal circuit element to form a first electrical interface. In such an example or any preceding example, the one or more conductive elements may be additionally or alternatively arranged in a mesh structure. In such an example or any preceding example, each of the one or more conductive elements may additionally or alternatively comprise a metal. Such an example or any preceding example may additionally or alternatively further comprise a liquid metal positioned within the channel.

Another example provides an electronic device comprising a plurality of connectors for connecting to a plurality of liquid metal circuit elements, the electronic device comprising a plurality of integrated liquid metal circuit elements, a connector system comprising an integrated plurality of connectors, each connector being connected to one of the plurality of integrated liquid metal circuit elements and each connector comprising a body defining a channel, the channel configured to contain a liquid metal circuit element, and a conductive path at least partially incorporated into the body, the conductive path comprising one or more conductive elements contained at least partially within the body and exposed to an interior of the channel to form a first electrical interface configured to interface with the liquid metal circuit element, and the conductive path also comprising a second electrical interface. Such an example or any preceding example may additionally or alternatively further comprise a liquid metal positioned within the channel. In such an example or any preceding example, the one or more conductive elements may each additionally or alternatively comprise a mesh structure. In such an example or any preceding example, the second electrical interface may additionally or alternatively be connected to one or more of a wire and a trace. In such an example or any preceding example, the body defining a channel may additionally or alternatively be configured as a male end of a mechanical connector.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A connector for a liquid metal circuit element, the connector comprising:
a body defining a channel configured to contain a liquid metal, the body being configured to interface mechanically with the liquid metal circuit element; and
a conductive path comprising a plurality of conductive elements disposed within the channel and exposed to an interior of the channel to form a first electrical interface configured to interface with the liquid metal circuit element, and the conductive path also comprising a second electrical interface.

2. The connector of claim 1, wherein the plurality of conductive elements each are formed at least partially from a metal.

3. The connector of claim 1, wherein the plurality of conductive elements comprises a mesh structure.

4. The connector of claim 1, wherein the body is formed from a polymer material.

5. The connector of claim 4, wherein the body is formed at least partially from a conductive polymer.

6. The connector of claim 1, wherein the conductive path is at least partially incorporated into the body.

7. The connector of claim 1, wherein the body defining the channel is configured as a male end of a mechanical connector.

8. The connector of claim 1, wherein each of the plurality of conductive elements is formed on a surface of the channel.

9. The connector of claim 1, wherein the second electrical interface is configured to connect to one or more of a wire and a trace.

10. The connector of claim 1, wherein the connector is integrated with a plurality of other connectors.

11. A connector system, comprising:
an integrated plurality of connectors, each connector comprising a body defining a channel configured to contain a liquid metal, the body being configured to interface mechanically with a liquid metal circuit element and incorporating a conductive path between a first electrical interface located at an interior surface of the channel and a second electrical interface.

12. The connector system of claim 11, wherein the conductive path further comprises one or more conductive elements exposed to an interior of the channel, the one or more conductive elements each being configured to interface with the liquid metal circuit element to form a first electrical interface.

13. The connector system of claim 12, wherein each of the one or more conductive elements comprises a mesh structure.

14. The connector system of claim 12, wherein each of the one or more conductive elements comprises a metal.

15. The connector system of claim 12, each of the one or more conductive elements is formed on a surface of the channel.

16. An electronic device comprising a plurality of connectors for connecting to a plurality of liquid metal circuit elements, the electronic device comprising:
a plurality of integrated liquid metal circuit elements;
a connector system comprising an integrated plurality of connectors, each connector being connected to one of the plurality of integrated liquid metal circuit elements and each connector comprising:
a body defining a channel, the channel configured to contain a liquid metal circuit element, and
a conductive path at least partially incorporated into the body, the conductive path comprising one or more conductive elements contained at least partially within the body and exposed to an interior of the channel to form a first electrical interface configured to interface with the liquid metal circuit element, and the conductive path also comprising a second electrical interface.

17. The electronic device of claim 16, wherein each of the one or more conductive elements is formed on a surface of the channel.

18. The electronic device of claim 16, wherein the one or more conductive elements each comprises a mesh structure.

19. The electronic device of claim 16, wherein the second electrical interface is connected to one or more of a wire and a trace.

20. The electronic device of claim 16, wherein the body defining a channel is configured as a male end of a mechanical connector.
